(19) United States
(12) Patent Application Publication
(10) Pub. No.: US 2025/0359196 A1
(43) Pub. Date: Nov. 20, 2025

(54) METAL-OXIDE-SEMICONDUCTOR ANOMALOUS HALL-EFFECT TRANCITOR

(71) Applicant: MAGNETON INC., Bronx, NY (US)

(72) Inventor: Duane GRANT, Bronx, NY (US)

(73) Assignee: MAGNETON INC., Bronx, NY (US)

(21) Appl. No.: 18/858,731

(22) PCT Filed: Apr. 17, 2023
(86) PCT No.: PCT/US2023/065863

§ 371 Date: Oct. 21, 2024

Related U.S. Application Data
(60) Provisional application No. 63/363,236, filed on Apr. 19, 2022.
(60) Provisional application No. 63/377,262, filed on Sep. 27, 2022.

(51) Int. Cl. H10D 48/00

(52) U.S. Cl. CPC H10D 48/385

(57) ABSTRACT

Disclosed are embodiments of a trancitor semiconductor device having a channel made of a ferromagnetic, ferrimagnetic or antiferromagnetic material, wherein the channel is interposed between a source, a drain, and a dielectric material adjacent to the channel. Two tap terminals adjacent to the dielectric material measure a voltage produced by an anomalous Hall effect (AHE) when current flows from the source to the drain. In an embodiment, a gate is provided that can modulate the conductivity of the channel. In an embodiment, no gate is provided and the extent of the voltage induced by the AHE is controlled only by a current applied at the source terminal. Planar and three-dimensional embodiments are also disclosed.

### FIELD OF THE INVENTION

This invention pertains to designs of trancitor semiconductor devices, relying on an anomalous Hall effect from current at a source terminal or voltage at a gate to control voltage through the device.

### BACKGROUND

A goal of semiconductor design is to develop electronic devices with increased complexity, density, and speed. This goal is expressed in Moore's law, positing that semiconductor device density will double every two years. Recent data shows this law has been correct for transistor counts on microchips from 1970 to at least 2020. This invention is directed to the goals of increasing complexity, density, and speed of semiconductor devices based on metal oxide semiconductor (MOS) technology and trancitor devices.

Transistors, as fundamental logic circuit units, have been developed over the past seven and a half decades, from the invention of the point-contact transistor to the current cutting-edge of metal-oxide-semiconductor field-effect transistor (MOSFET) in nanosheet and gate-all-around configurations. Technological strides have been taken as devices moved from process nodes and gate lengths on the order of centimeters down to the order of tens of nanometers, to the point where current cutting-edge options use a 5 nm process for MOSFET devices. Due to fundamental limitations of semiconductor devices, the advancing design of transistors has required innovations to resolve issues of directly scaling node lengths down in an effort to avoid inoperable transistors due to quantum effects and current leakage, among other problems. This includes for example, the development of the fin field-effect transistor (FinFET) [1] and gate-all-around MOSFET (GAAFET) [2] devices.

A significant roadblock to widespread implementation is manufacturability, as both planar and non-planar designs present significant challenges, especially with respect to lithography and patterning.

Inevitably, new device designs will be needed that utilize different methods of action that optimize the operation of electronics. Further still, future devices will likely need to go beyond the limits of complementary metal-oxide-semiconductor (CMOS) electronics as a whole, into more advanced and more efficient methods that enhance operation and provide bridges to more advanced technologies beyond them.

The novel transfer-capacitor, or “trancitor,” [3] is one such device, optimizing the function of current transistor-based devices and laying fertile ground for post-CMOS technologies. As a result of its construction and operation mechanism, focus can be placed on circuit configuration as a means of advancing chips and processors. Likewise, a revival of direct length scaling beyond current 5 nm and next-generation 3 nm can be potentially achieved.

Lee [3] disclosed a theoretical list of elementary active devices deduced from four possible combinations of the current and voltage at the input and output (FIG. 1). Lee suggests that “trancitors” are missing as a current-controlled/voltage source (CCVS) or voltage-controlled/voltage source (VCVS) active devices. These hypothetical CCVS or VCVS devices are in contrast to conventional field-effect transistors and bipolar junction transistors that are voltage controlled/current source (VCCS) and current controlled/current source (CCCS) devices respectively.

The current form of transistor used for modern processing technologies utilizes the field effect, whereby application of an external electric field at a gate terminal modulates the electrical conductivity of the transistor channel, the active region of the device. For an enhancement mode MOSFET, an applied voltage increases conductivity in the channel by altering how many energy levels are available to charge carriers, lowering the edge of the conduction band, and increasing the population of charge carriers (i.e., electrons or electron holes) in the conduction band. This is evidenced by the conduction band moving closer to the Fermi level, and the inverse occurs for a depletion mode MOSFET. That is, in a depletion mode MOSFET, an applied voltage decreases conductivity in the channel.

Similarly, in an extrinsic semiconductor with both magnetic and electronic doping, this field effect would occur via an applied voltage over an optional gate component, wherein the gate is comprised of an outer metal or highly doped semiconductor contact and an inner insulating/gate dielectric layer (hafnium oxide/HfO₂, silicon dioxide/SiO₂, etc.). This layer can also be an insulating perovskite material (e.g., strontium titanate/SrTiO₃) [4] or a superlattice of dielectric material, enhancing capacitive effects, voltage control and subthreshold swing. However, due to the introduction of transition metals into the structure, there is a coupling interaction between charge carriers and magnetic moments, whereby intrinsic magnetic effects, including magnetization, can be modulated by applying a voltage to the material. [5]

### SUMMARY OF THE INVENTION

This disclosure provides embodiments of VCVS and CCVS semiconductor trancitor devices relying on an anomalous Hall effect to control voltage through the device. Planar and three-dimensional embodiments are disclosed.

In an embodiment, this disclosure pertains to a metal-oxide-semiconductor voltage controlled anomalous Hall-effect trancitor (MOSHET) (100), including: (a) A semiconductor substrate (152), an active layer (172) and channel (170) wherein the active layer and channel may be formed from a ferromagnetic, ferrimagnetic, or antiferromagnetic material; (b) a source terminal (110) and drain terminal (120), and two Hall effect terminals (160/162) orthogonal to the source and drain terminals on the channel, a body terminal (150), and a gate terminal (130); (c) wherein a voltage applied to the gate terminal increases the conductivity of the channel (170) between the source and drain in an enhancement mode and reduces the conductivity of the channel in a depletion mode; and (d) wherein application of an electric field through the channel between the gate and body produces a Berry curvature in the channel that causes an anomalous Hall effect (AHE) that generates a voltage between the two Hall effect terminals.

In an embodiment, this disclosure pertains to a MOSHET wherein the channel (170) is a cube or cuboid having three orthogonal axes through opposing faces of the cube or cuboid, wherein the axes include connections to: (1) the gate and substrate, (2) the source and drain; and (3) the two tap Hall terminals.

In an embodiment, this disclosure pertains to a metal-oxide-semiconductor anomalous Hall-effect trancitor (MOSHET), including: (a) a semiconductor substrate (152), an active layer (172) and channel (170), wherein the active layer and channel may be formed from a ferromagnetic or ferrimagnetic material; (b) a source terminal (110) and drain terminal (120), and two Hall effect terminals (160/162) orthogonal to the source and drain terminals on the channel, and a body terminal (150); (c) wherein application of a current through the channel between the source and the drain generates a voltage between the two Hall effect terminals from an intrinsic anomalous Hall effect (AHE); (d) wherein magnitude of the current in the channel (170) between the source and drain controls the AHE.

In In an embodiment, this disclosure pertains a three-dimensional metal-oxide-semiconductor voltage controlled anomalous Hall-effect trancitor (MOSHET) (102, 104), including a substrate (152) with a fin and gate structure (122, 130) wrapping around a channel (170), wherein a source (110) and drain (120) are contiguous with the channel, and wherein the source, channel, and drain are oriented perpendicular to the gate structure (130); wherein a shallow trench layer (144) wraps around each of the source in drain and in contact with the substrate; and wherein a pair of tap Hall terminals (160, 162) are perpendicular to the substrate and adjacent to the drain fin and optionally have a dielectric layer (142) interposed between each terminal and the drain fin.

In In an embodiment, this disclosure pertains three-dimensional MOSHET, further including contact points at the gate (130), the lower surface (150) of the substrate, the source (110), the drain (120), and at each tap Hall terminal (160, 162).

In In an embodiment, this disclosure pertains a three-dimensional MOSHET, wherein a voltage at the gate (130) modulates the conductivity of channel (170) between the source and drain and an anomalous Hall effect at the fin (122).

In In an embodiment, this disclosure pertains a three-dimensional MOSHET, further including contact points at the lower surface (150) of the substrate, the source (110), the drain (120), and at each tap Hall terminal (160, 162).

In In an embodiment, this disclosure pertains MOSHET (104), wherein the source, channel, and drain is subdivided into two or more segments (111, 171, 121) parallel to the substrate with an interstitial space (124) between each segment; wherein the source, channel, and drain segments each form a contiguous unit; and wherein optionally dielectric layers (140) are interposed between channel segments (171).

In an embodiment, this disclosure pertains to a metal-oxide-semiconductor anomalous Hall-effect trancitor including: (a) an active layer (172) supported by a substrate layer (152), a source (110) and drain (120), wherein the source (110) may be either a p-doped or n-doped semiconductor and the drain (120) is the inverse, n-doped or p-doped, respectively; wherein an intermediate active layer channel (170) is interposed between the source and drain; wherein the active layer (172) material is a magnetic semiconductor which can be crystalline or amorphous (metallic glass-based); (b) wherein orthogonal to both the primary gate and the source/drain terminal pair are two tap Hall terminals (160, 162), which measure the output voltage from the anomalous Hall effect within the channel.

In In an embodiment, this disclosure pertains metal-oxide-semiconductor anomalous Hall-effect trancitor, wherein the magnetic semiconductor is crystalline and includes a Si-based, II-IV, III-V semiconductor; or wherein the magnetic semiconductor is amorphous and includes a metallic glass-based semiconductor.

In an embodiment, this disclosure pertains to a trancitor, wherein the active layer material is a ferromagnetic, ferrimagnetic, or antiferromagnetic material.

In an embodiment, this disclosure pertains to a trancitor, wherein the active layer magnetic semiconductor is amorphous CO_{28.6}Fe_{12.4}Ta_{4.3}B_{8.7}O₄₆ (a-CFTBO).

In an embodiment, this disclosure pertains to a trancitor, wherein a secondary insulating layer (174) is sandwiched between the active layer (172) and the substrate layer (174), wherein the secondary insulating layer (174) is made of similar material to the primary insulating layer of the gate.

In an embodiment, this disclosure pertains to a trancitor, wherein a thin layer of ferromagnetic, ferrimagnetic or antiferromagnetic material forming a gate layer (154) is sandwiched between the channel (170) and the substrate layer (152); wherein a magnetic anisotropy of the gate layer (154) remains fixed; wherein an electric field at the gate layer (154) modifies the magnetic anisotropy of layer (172) causing a magnetization rotation so that the relative magnetization configuration of layer (172) is modulated; and wherein the magnetic anisotropy of layer (172) creates a low resistance state and a high resistance state.

### DESCRIPTION OF THE DRAWINGS

FIG. 1 is a prior art diagram (from Lee [3]) of theoretical elementary active devices deduced from four possible combinations of the current and voltage at the input and output.

FIG. 2 is an isometric view of the structure of a planar transfer-capacitor/trancitor MOSHET according to this invention.

FIG. 3 is a set of proposed symbols for the inventive trancitor.

FIG. 4 is a transverse top view of the MOSHET of FIG. 2.

FIG. 5 is a side-view of the planar MOSHET of FIG. 2.

FIG. 5A is a cross section through a MOSHET as in FIGS. 2, 4, 5. The cross section is through the line marked Q-Q′ in FIG. 4

FIG. 6 is an isometric view of the structure of a trancitor FinHET.

FIG. 7 is an isometric view of the structure of a trancitor GAAHET.

FIG. 8 is an elevation view of the front of the FinHET device, from viewpoint A in FIG. 6.

FIG. 9 is an elevation view of the back of the FinHET device, from viewpoint C in FIG. 6.

FIG. 10 is an elevation view of the front of the GAAHET device, from viewpoint A in FIG. 7.

FIG. 11 is an elevation view of the back of the GAAHET device, from viewpoint C in FIG. 7.

FIG. 12 is a side elevation view of the FinHET device, from viewpoint B in FIG. 6.

FIG. 13 is a side elevation view of the GAAHET device, from viewpoint B in FIG. 7.

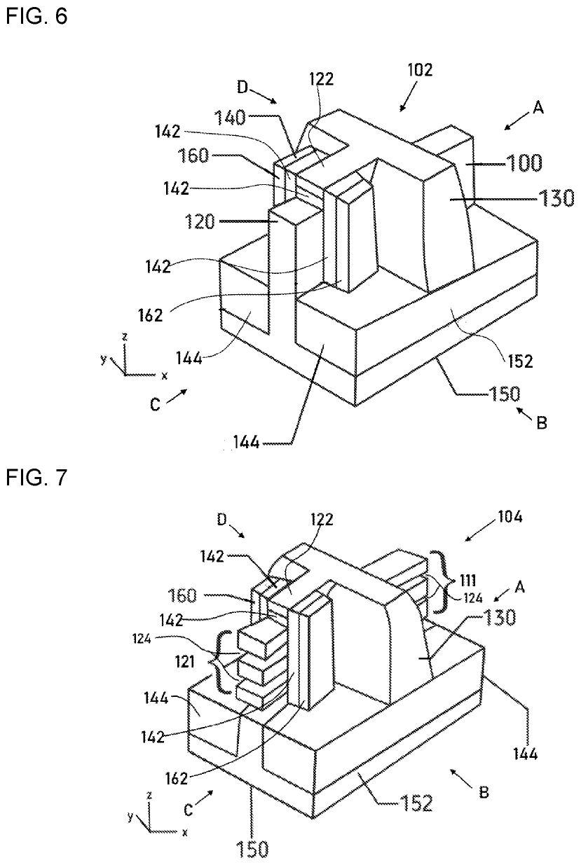

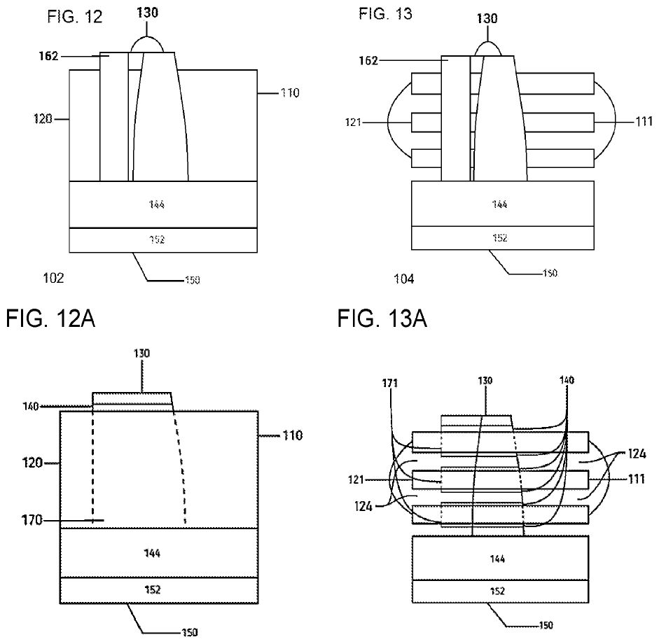

FIG. 12A is a cross section view through a FinHET device according to FIGS. 6, 8, 9, 12, and 14. The cross section is through the line marked R-R′ in FIG. 14.

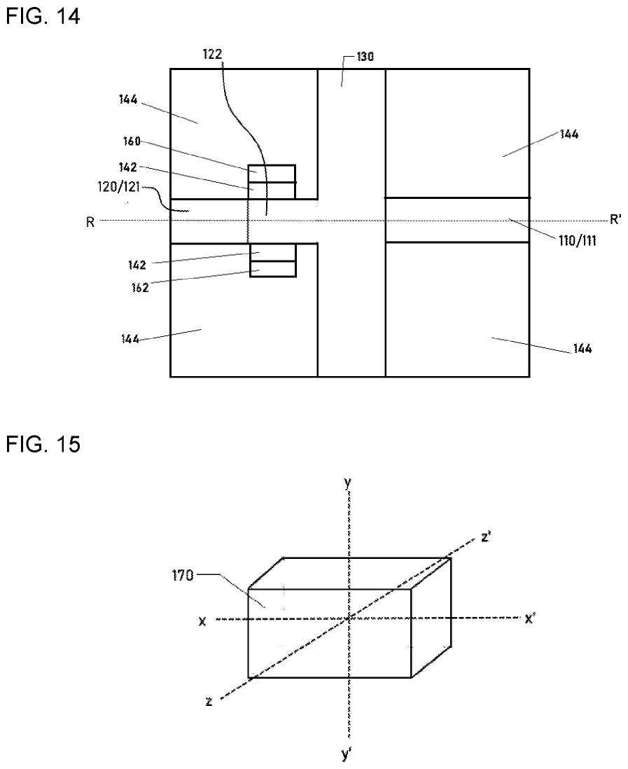

FIG. 13A is a cross section view through a GAAHET device according to FIGS. 7, 13, and 14. The cross section is through the line marked R-R′ in FIG. 14.

FIG. 14 is a FinHET/GAAHET-overhead elevation view.

FIG. 15 is an isometric view of a cuboid channel 170 showing three orthogonal axes through the cuboid.

### DETAILED DESCRIPTION

Disclosed herein is a semiconductor trancitor device that includes enhancement and depletion modes as in a MOSFET but relying on an anomalous Hall effect to gate the voltage switched by the device. Given the architecture and functionality of the device, it is apt to call the inventive device a “metal-oxide-semiconductor Hall-effect trancitor,” or MOSHET.

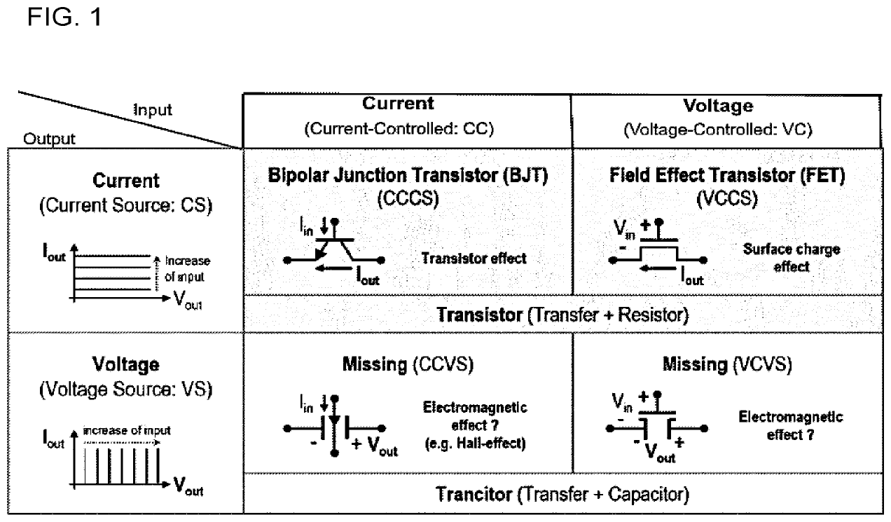

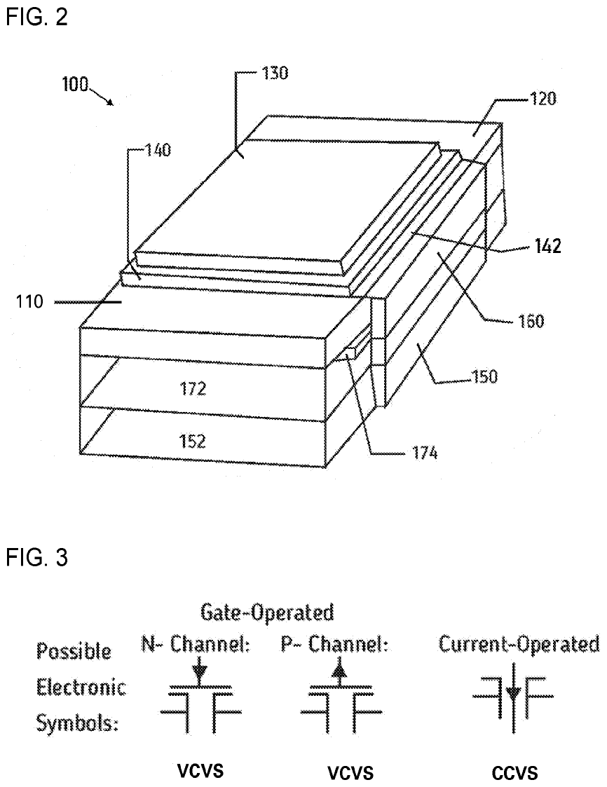

Lee [3] proposed a hypothetical active device (see FIG. 2 in Lee [3]) relying on a Hall effect to gate voltage through the device and produce a voltage potential between two Hall terminals (FIG. 1). The Hall effect is a voltage difference (the Hall voltage) across an electrical conductor that is transverse to an electric current in the conductor and to an applied magnetic field perpendicular to the current.

This disclosure provides two variations on the hypothetical active devices of Lee: (1) a current-source voltage-controlled (CCVS) device, and (2) a voltage-controlled voltage-source (VCVS) device. Lee [3] proposed no specific semiconductor structure for either of these devices. Moreover, the inventive devices rely on an anomalous Hall effect, not a conventional Hall effect as suggested by Lee.

In an embodiment, a metal-oxide semiconductor anomalous Hall-effect trancitor (MOSHET) (100) is disclosed. In an embodiment, the MOSHET is a VCVS device. The MOSHET may have a semiconductor substrate (152), and an active layer (172) and channel (170). The active layer and channel are contiguous and are fabricated from a ferromagnetic, ferrimagnetic, or antiferromagnetic material. The VCVS device may be equipped with a source terminal (110), drain terminal (120), and two Hall effect terminals (160/162) orthogonal to the source and drain terminals on the channel, a body terminal (150), and a gate terminal (130). A voltage applied to the gate terminal increases the conductivity of the channel between the source and drain in an enhancement mode and reduces the conductivity of the channel in a depletion mode. The application of an electric field through the channel between the source and drain produces a Berry curvature in the channel that causes an anomalous Hall effect (AHE) that generates a voltage between the two Hall effect terminals.

In another embodiment, the MOSHET may be a current-source voltage-controlled (CCVS) device. This device may include a semiconductor substrate (152), an active layer (172) and channel (170) each comprising a ferromagnetic or ferrimagnetic material. The device further includes a source terminal (110) and drain terminal (120), and two Hall effect terminals (160/162) orthogonal to the source and drain terminals on the channel, and a body terminal (150). The application of a current through the channel between the source and the drain generates a voltage between the two Hall effect terminals from an intrinsic AHE. The conductivity of the channel between the source and drain is controlled by the current applied at the source terminal.

### Anomalous Hall Effect

The inventive device relies on an anomalous Hall effect (AHE) to gate voltage through a CCVS or VCVS device. The AHE is a form of Hall effect wherein charge carriers acquire a velocity orthogonal to an applied electric field without an applied magnetic field. This occurs due to broken time-reversal symmetry that, in the normal Hall effect, would be induced by an external magnetic field. In the case of the AHE, a Berry Curvature takes the place of an externally applied magnetic field, typically illustrated as B_{z}, meaning a magnetic flux density along the z axis. [6] The Berry Curvature is the vector field of the Berry phase term of the solution to the Schrödinger equation for the phase of a charged particle. The Berry Curvature modulates the paths of charged particles, such as electrons, within momentum space; in this way, it acts like a kind of momentum-space version of a normal magnetic field. Under transformations that flip the sign of the momentum vector, such as spatial inversions (which leave the sign of the Berry Curvature unchanged) and time reversals (which flip the sign of the Berry Curvature), the magnitude of the Berry Curvature can only be the trivial solution of zero unless other symmetries are broken. This can be accomplished by application of a large enough electric field, an electrostatic potential varied by the configuration of a material's constituent particles, or strain, for instance.

In ferromagnetic, ferrimagnetic and non-collinear antiferromagnetic materials, an AHE can be observed without many other prerequisites; however, due to the inherent time-reversal symmetry and crystal group space symmetry of compensated antiferromagnets (as described in [6]), linear AHE is not possible, but a nonlinear AHE is possible within non-centrosymmetric antiferromagnets (for example CuMnAs and CuMnSb [6]).

A ferrimagnetic material is a material that has populations of atoms with opposing magnetic moments, as in antiferromagnetism, but these moments are unequal in magnitude so a spontaneous magnetization remains. This can for example occur when the populations consist of different atoms or ions (such as Fe²⁺ band Fe³⁺). Some representative ferrimagnetic materials include magnetite. Fe²⁺Fe³⁺₂O₄, ReFe₂O₄, PbFe₁₂O₁₉, BaFe₁₂O₁₉, and CoFe₂O₄. [7]

Antiferromagnetism is the manifestation of a magnetic order that has two or more magnetic sublattices aligned in such a manner that the total moment is zero. [8], [9] Other antiferromagnetic materials include BiFeO₃ (BFO) [10], [11], RuO₂[12], CuMnAs [13], [14], tetragonal LiMnAs [15].

Ferromagnetism is a property of certain materials (such as iron) that results in a significant, observable magnetic permeability, and in many cases, a significant magnetic coercivity, allowing the material to form a permanent magnet. Ferromagnetic materials are familiar metals that are noticeably attracted to a magnet, a consequence of their substantial magnetic permeability. Magnetic permeability describes the induced magnetization of a material due to the presence of an external magnetic field. This temporarily induced magnetization, for example, inside a steel plate, accounts for its attraction to the permanent magnet. Ferromagnetic materials that may be of value in this invention include cubic LiZnAs, Li(Zn,Mn)As [15] and SrTiO₃ [4]. Ferrimagnetic materials are discussed in references [7], [16], [17].

In a CCVS embodiment, the channel and active layer 170/172 may be ferromagnetic or ferrimagnetic, but not antiferromagnetic, because the AHE relies on breaking the time symmetry in the active layer, and this occurs intrinsically with ferromagnetic or ferrimagnetic materials but not with antiferromagnetic materials.

The AHE describes the current of conduction electrons, which is created perpendicularly to an electrical current in a ferromagnetic metallic wire due to the spins of the localized d− electrons. The AHE exists due to the magnetic interaction of localized and conduction electrons. [12], [18] The output voltage, or Hall voltage, is measured as the potential difference transverse to the flow of current in the device, between a pair of tap terminals on a semiconductor channel. An AHE is an intrinsic effect, meaning that the Hall voltage is generated without the application of an external magnetic field.

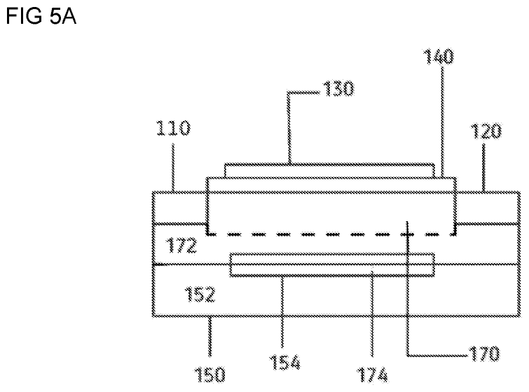

Thus, in operation, one tap terminal (e.g., 160) outputs a voltage measurement with respect to a reference or ground connected to the other tap terminal (e.g., 162). A gate terminal 130 may be provided (in a VCVS embodiment) adjacent to a layer of insulating dielectric material 140 for better internal electric field control (FIG. 2), while the tap terminals can be optionally isolated by thin tap dielectric layers 142 (FIGS. 6, 7). The aforementioned elements may be attached to a material substrate layer 152 that makes up the body terminal 150 of the device, with an optionally embedded double-layer system of an internal, secondary insulating layer or barrier 174. Also optional is a floating gate layer 154 (FIG. 5) that can act as a digital or analog memory system.

### Embodiments

An embodiment of a planar MOSHET device 100 according this disclosure is shown in FIGS. 2, 4, 5, and 5A. Device 100 is similar to a MOSFET. The element sub-architecture involves a total of five or six terminals, wherein a semiconductor substrate layer 152 (part of which comprises the body of the device) supports an active layer 172, a source 110, drain 120, and optionally a gate 130. The source 110 may be either a p-doped or n-doped semiconductor. Drain 120 is the inverse of the source polarity, n-doped or p-doped, respectively. Gate 130 may be a conductor such as a metal, silicide or doped polysilicon. Between the source, drain and the substrate is an intermediate active layer, part of which comprises channel 170. In an embodiment, the material of the active layer 172 is a form of ferromagnetic semiconductor [19] which can be crystalline (Si-based, II-IV, III-V, etc.) or amorphous (metallic glass-based).

In a VCVS embodiment (shown in FIGS. 2, 4, and 5), there may be six terminals, including the source 110, drain 130, first tap/Hall contact 160, second tap/Hall contact 162, gate 130, and body terminal 150. In a CCVS embodiment, the gate is excluded, making five terminals.

Proposed electronic symbols are shown in FIG. 3, indicating six terminals in the VCVS variation, shown as a Gate-Operated N-Channel or P-Channel, and five terminals in the CCVS variation, marked as Current Operated. There is no gate in the CCVS variation.

Charge carriers in channel 170 and active layer 172 induce a magnetic field which induces a voltage from an AHE. Channel 170 and active layer 172 may be fabricated from a ferromagnetic, ferrimagnetic, or antiferromagnetic semiconductor material in a VCVS device. In a CCVS device the material may be ferromagnetic or ferrimagnetic. An exemplary ferromagnetic semiconductor material is amorphous CO_{28.6}Fe_{12.4}Ta_{4.3}B_{8.7}O₄₆ (a-CFTBO), [19] which is capable of being produced and implemented via standard sputtering techniques already present and widely used in commercial semiconductor production. While a-CFTBO is naturally a p-type semiconductor (corresponding to n-type semiconductor source, drain and body), an n-type magnetic semiconductor material can also be used. Likewise, an Fe-doped III-V semiconductor material (such as (Ga,Fe)Sb, [20] (In,Fe)Sb, [21] etc.) or another ferromagnetically-doped Si/SiGe [22] material can be utilized as intrinsic ferromagnetic semiconductors with electronic and doping behavior more closely aligned with contemporary semiconductor devices. A ferromagnetically doped Si/SiGe can be continuous with the substrate layer (which itself would be Si/SiGe). [23] By contrast, a-CFBTO would be applied as a thin film to the Si/SiGe substrate. Another ferromagnetic semiconductor is manganese-doped silicon. [24]

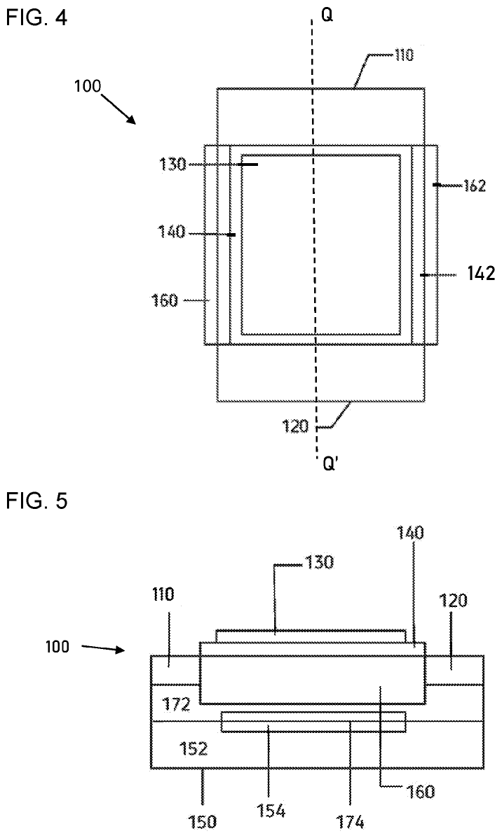

Channel 170 is contiguous with active layer 172. This is illustrated in FIG. 5A, which is a cross section through the device of FIGS. 2, 4, and 5 along the line Q-Q′ in FIG. 4. This cross section shows 170 embedded in the device 100. In an embodiment, channel 170 is a cube or cuboid structure. The three orthogonal axes through opposing faces of the cube or cuboid have electronic connections to: (1) the gate (if present) and substrate, (2) the source and drain; and (3) the two tap Hall terminals. These axes are illustrated in FIG. 15. For example, the gate may be at x, and the substrate terminal at x′; the source may be at y, and the drain at y′; and the two tap Hall terminals are at z and z′. Because 170/172 is fabricated from a ferromagnetic, ferrimagnetic or antiferromagnetic material (in a VCVS embodiment), each of these axes have different properties. Thus, a voltage at gate 130 and terminal 150 (in contact with substrate 152) modulates current flow on the source-drain axis by changing the magnetization of the channel, which increases or decreases the magnitude of the anomalous Hall effect at a constant current. When a current is flowing on the source-drain axis, an AHE creates a voltage between the tap Hall terminals 160/162. Each of these effects occurs on an axis orthogonal to the other two axes of channel 170. In a CCVS device, there is no gate, so in that embodiment, there are only two active axes—the source-drain and AHE voltage.

Optionally, device 100 may include a thin secondary insulating layer 174, also termed a barrier, sandwiched between the active layer 172 and substrate layer 152. Barrier 174 may be made of similar material to the primary insulating layer (140) of gate 130. Also sandwiched between the barrier and the substrate layer can be a thin layer of ferromagnetic semiconductor 154, similar to that of the active layer 172, which acts similar to a magnetoresistive counterpart to the floating gate of a floating gate MOSFET with different functionality. Likewise, the device can also have the contemporary floating gate structure of a floating gate MOSFET, with or without the magnetoresistive floating gate.

If present, the barrier 174 and secondary thin ferromagnetic layer 154 (along with the ferromagnetic material in the active layer) are designed to be an axial magnetic tunnel junction. [25] An axial magnetic tunnel junction exhibits a magnetoresistive effect at room temperature, that has been applied to memory devices. Applying a voltage at the gate 130 can switch the magnetization of the active layer 172 with respect to the thin layer 154. Parallel magnetization yields a low-resistance state, and antiparallel magnetization yields a high-resistance state, and any angle from 0-180° between the relative magnetizations induces an increasing electrical resistance as θ->180°, and the reverse as θ->0°. This mirrors the capacitive nature of the secondary gate in a floating-gate MOSFET, where electrons are trapped in the floating gate after the transistor is switched. This isolated charge acts as a bit of information that can be stored for long periods of time (>10 years). Likewise, the resistance state can be read through the voltage between the gate and body terminals and can be stored for long periods of time. While the floating-gate MOSFET can and is used in conventional, non-volatile flash memory, this can be used as a magnetic counterpart to that same flash memory with similarly low volatility.

Orthogonal to both the primary gate and the source/drain terminal pair are the final two terminals (160 and 162), representing a pair of conducting material contacts. Terminals 160/162 are adjacent to channel 170. Optionally, a dielectric layer 142 is interposed between each of terminals 160 and 162 and channel 170. This dielectric may impart capacitance to the interface between 170 and each tap terminal. Dielectric 142 is illustrated in FIGS. 2 and 4. Terminals 160/162 are the Hall contacts, or “tap” or “tap Hall” terminals of the trancitor. In operation, a Hall voltage potential is produced between the tap terminals. Like the MOSFET structure, the trancitor can, based on its own structure, also have enhancement and depletion modes. In an enhancement mode, voltage applied to the gate terminal increases the conductivity of the device. In a depletion mode, voltage applied at the gate reduces the conductivity.

### Operation

In general terms, in a VCVS embodiment of a MOSHET, a voltage applied to gate 130 modulates current flow in channel 170 between source 110 and drain 120, and the current in the channel induces a voltage from an AHE between tap terminals 160 and 162. A voltage is also measured between gate 130 and body terminal 150.

In a CCVS embodiment, the gate is not used, so the AHE voltage is only controlled by the amount of current in channel 170 between source 110 and drain 120. A voltage is measurable between the source 110 or drain 120 and body terminal 150. A CCVS device is defined by a lack of a modulating input voltage at a gate (e.g., 130). This differentiates two forms of trancitor devices: gate-operated (voltage controlled, voltage source) and current-operated (voltage controlled, current source). In a VCVS mode, a voltage source modulates the output voltage through charge carrier-magnetic moment interactions the active layer. In a CCVS mode, a current source modulates the output voltage directly through the anomalous Hall effect.

Thus, both the CCVS and VCVS devices are within the scope of this disclosure, depending on configuration. For instance, in a VCVS embodiment, the gate 130 and gate dielectric 140 are present. In that embodiment, the gate 130 uses a voltage to directly modulate the output voltage measured by the tap contacts. This occurs because the gate voltage changes the magnetization of the channel, which increases or decreases the magnitude of the anomalous Hall effect at a constant current. In a CCVS embodiment, the gate and the dielectric layer beneath the gate are absent, and the magnitude of the current applied at source 110 instead directly modulates the output voltage across terminals 160 and 162, while the magnitude and direction of the magnetization stay the same.

Operationally, the source terminal (110, FIGS. 2, 4, 5) is a charge carrier provider in the form of current when a current is applied to 110. The drain terminal 120, by contrast, is the charge carrier acceptor in the device, and the channel 170 is the path of material crossed by the current flow from source 110 to drain 120 or drain to source, depending on carrier type. The channel 170 is a portion of the active layer 172, labeled as such due to being the material site of the primary method of action of the device that is controlled by the gate terminal 130 of the device. Beside the channel are the tap terminals (160, 162), which measure the output voltage from the anomalous Hall effect (AHE) within the channel.

When a current source introduces an input current into source terminal 110 of the device, the current passes into the active layer 172. Much like the MOSFET counterpart, in an enhancement mode MOSHET, a voltage applied to the gate terminal 130 increases the conductivity of active layer 172 from a default “off” state when layer 172 is either n- or p-doped. In a depletion mode MOSHET, voltage applied to the gate reduces the conductivity of active layer 172 from a default “on” state. Upon activation via the gate of the device, the top region of the device (i.e., 130/140) functions as a capacitor to allow for voltage control and, as a result, generate a local electrical field extending into the substrate layer 152 of the device. This electric field attracts charge carriers towards the gate 130 that are momentarily interrupted by dielectric layer 140, confining the charge carriers and increasing the carrier concentration in that region, while depleting charge carriers in the bottom region of the device, i.e, at substrate 152. The voltage applied from gate 130 to the active layer 172 (which may comprise a ferromagnetic, ferrimagnetic, or antiferromagnetic material) and an increase in carrier concentration thus increases the saturation magnetization of the material of layer 172 through exchange interactions between the charge carriers and magnetic moments in the material, enhancing its ferromagnetic character.

This magnetic character of the active layer 172 allows for the application of an anomalous Hall effect on charges comprising the input current, whereby the net magnetization of this magnetic semiconductor element allows for a magnetic field that extends out-of-plane into the channel path 170. Charge carriers are allowed through the channel 170 but deviate more strongly due to the magnetic field and adopt curved paths distinct from the net line-of-sight path from source to drain at zero/lower magnetization. The remaining current running through the device exits through the drain 120 of the device.

With an insufficient or below-threshold voltage at gate 130, a weaker electric field is generated in channel 170, which results in a weaker carrier concentration enhancement and magnetization effect, thereby reducing the AHE induced voltage between tap terminals 160 and 162. The deviated paths of the charge carriers due to the field induce a potential difference, or voltage output, that can be measured on one Hall contact/Tap terminal, for example 160, optionally isolated by thin dielectric layers, with respect to the opposite-side terminal (i.e., 162). This effect allows for a current-controlled, voltage-source (CCVS) device with an output voltage at terminals 160/162 that depends directly on the magnitude of the input current at the source terminal 110. Note that for both CCVS and VCVS devices, a current is applied to the source and exits at the drain, and a voltage is generated between of the taps by the AHE. In CCVS devices, the magnitude of the current at the source directly modulates the magnitude of the tap voltage, whereas in VCVS devices, the gate voltage at 130 modulates the tap voltage through magnetization.

In a floating gate version of the device, tunneling magnetoresistance (TMR) is utilized. [26] The magnetization of the active layer 170 “pins” (or fixes) the magnetization of an interior ferromagnetic gate layer 154, resulting in a comparatively lower resistance through the floating gate/barrier 174 that is embedded within the base substrate 152, than a magnetically anisotropic configuration of the two layers. That is, an electric field at ferromagnetic gate layer 154 modifies the magnetic anisotropy of layer 154 leading to its magnetization rotation so that the relative magnetization configuration of layer can be efficiently modulated. A low resistance state, compared to a high resistance state, can be measured via a below-threshold voltage between the top gate 130 and body contact 150 and can be erased with a reverse-polarity voltage that switches the relative magnetization of the two layers. Through the utilization of TMR, the structure can be functionally equivalent to a magnetic tunnel junction capable of non-volatile data storage within the device at lower power draws than contemporary electrically erasable methods.

The device is expected to be compatible with conventional CMOS manufacturing processes and can also be further miniaturized in conjunction with MOSFET node scaling. The form factor of a planar MOSFET can be matched with the planar MOSHET, the FinFET and the GAAFET with the FinHET and GAAHET.

### Three Dimensional Embodiments

Three dimensional (3D) transistors include FinFET and GAAFET devices. A fin field-effect transistor (FinFET) is a multigate device, a MOSFET (metal-oxide-semiconductor field-effect transistor) built on a substrate where the gate is placed on two, three, or four sides of the channel or wrapped around the channel, forming a double or even multi gate structure. These devices are termed “FinFETs” because the source/drain region forms “fins” as three-dimensional features on the silicon substrate surface. Gate-all-around field-effect transistors (GAAFET), also known as a surrounding-gate transistor (SGT), are similar in design to a FinFET except that the gate material surrounds the channel region on all sides by segmenting the fin. Depending on design, gate-all-around FETs can have two or four effective gates. These 3D devices have significantly faster switching times and higher current density than planar CMOS (complementary metal-oxide semiconductor) technology.

In a FinHET (fin Hall-effect trancitor) embodiment of the device (102, FIGS. 6, 8, 9, 12, 12A and 14), a substrate (152) is provided with a fin and gate structure (122, 130) wrapping around a channel 170 (FIG. 12A). A source (110) and drain (120) are contiguous with the channel. FIG. 12A illustrates channel 170 interposed between the source and drain. The fin 122 and gate 130 may be a contiguous T-shaped unit (this is shown in FIG. 6) that may be fabricated from a ferromagnetic, ferrimagnetic, or antiferromagnetic semiconductor material. The source, channel, and drain are oriented perpendicular to the gate structure (130) and are also perpendicular on a different axis with respect to the substrate. A shallow trench layer (144) may wrap around each of the source and drain and in contact with the substrate. A pair of tap Hall terminals (160, 162) are perpendicular to the substrate and adjacent to the drain fin, with an optional dielectric layer (142) interposed between each terminal and the drain fin. The gate extends over the drain-side of each channel to allow continuity of magnetization control in these subregions.

Interposed between the gate 130 and substrate 152 is a shallow trench isolation dielectric 144, or STI dielectric, which electronically isolates adjacent fins from one another to allow for precise control of each channel, for example with an ensemble of FinHET devices on a semiconductor wafer having rows of FinHET assemblies. Likewise, a wafer can contain multiple units of FinHET assemblies (similar to a FinFET), whereby the STI allows for the fins of each unit to be isolated from one another except for their connection to a common gate. This allows for better control of the channel of each fin. This can be applied in the case of GAAHET devices also. Such an ensemble can be constructed by ganging discrete devices along the B-side of FIGS. 6 and 7 to the D-side of the next device, in a repeating formation of the devices in a line.

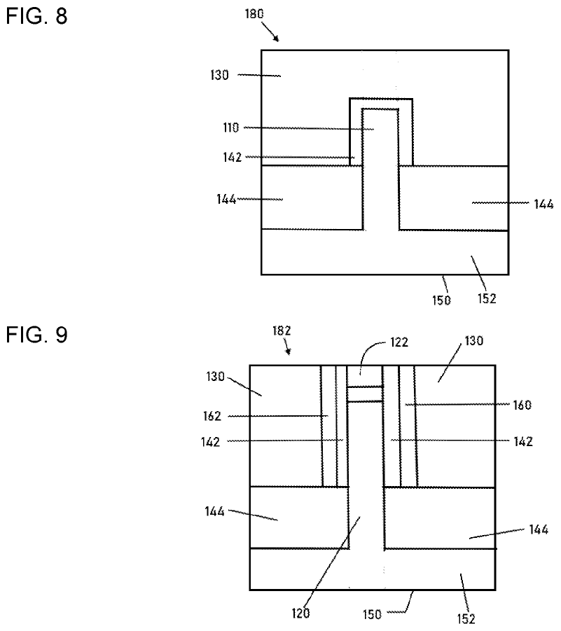

The tap terminals 160 and 162 extend down the drain-side channels alongside the portion of drain 120, forming part of the “fin”, to measure the Hall voltage as the current flows through the device from source to drain. Terminals 160/162, and tap dielectrics 142 (if present) are perpendicular to the plane of 152, that is, the 160/162 and 142 are situated in a vertical orientation relative to the plane of the substrate. Thus, the channel where the AHE is induced in the FinHET is effectively the fin portion (122) of the drain 120. As illustrated in FIGS. 6, 8. 9, 12, and 14, tap terminals 160/162 can be further optionally isolated by thin tap dielectric layers 142. Much like a FinFET, this configuration allows better control over the conductivity of the channel of each fin for a given unit voltage. Likewise, this allows better control over the magnetization and scaling down to smaller effective process nodes.

FIG. 6 is a perspective view of the inventive FinHET device 102. FIG. 8 is an elevation view of the back of the FinHET device, from viewpoint A in FIG. 6. This is facing the source side, marked 180. FIG. 9 is an elevation view of the front of the FinHET device, from viewpoint C in FIG. 6. This is facing the drain side, marked 182. FIG. 12 is a side elevation view of the FinHET device, from viewpoint B in FIG. 6. FIG. 12A is a cross section of the FinHET device of FIGS. 6, 8, and 9, illustrating the location of channel 170 which is not visible in FIG. 6. FIG. 14 is an overhead view of device 102.

A FinHET device can act in a VCVS mode or a CCVS mode. A FinHET may have six contact points, at the gate (130), the lower surface (150) of the substrate, the source (110), the drain (120), and at each tap Hall terminal (160, 162). In a VCVS mode, a current is applied between the source 110 and drain 120. A voltage applied at gate 130 modulates the conductivity between the source and drain and thus the current flowing in channel 170. In an enhancement mode, voltage applied to the gate terminal increases the conductivity of the device. In a depletion mode, voltage applied at the gate reduces the conductivity. The current flowing between the source and drain create an AHE and the output voltage at tap Hall terminals 160 and 162.

In a CCVS mode, the contact on gate 130 is absent, or if present, is not used. Also, the material of gate 130 and fin 122 would be a ferromagnetic or ferrimagnetic material, not an antiferromagnetic material. In a CCVS mode, the AHE is dependent only on the current flowing between the source and drain.

In a GAAHET (gate all-around Hall effect trancitor) embodiment (104 FIGS. 7, 10, 11, 13, 13A, and 14), the same principle of the FinHET is applied, but structurally the source, channel, and drain, are subdivided into two or more shelf-like segments (111, 171, 121) parallel to the substrate with an interstitial space 124 between each segment. FIGS. 7, 13 and 13A illustrate an embodiment with three segments (111, 171, 121) but there can be as few as two segments or additional segments, such as four, five, six, or more segments. As with the FinHET embodiment, each source-channel-drain segment has contiguous regions for the source, channel, and drain (FIG. 13A). Optionally, there may also be dielectric layers (140) are interposed between channel segments 171. FIG. 13A is a cross section through line R-R′ in FIG. 14, illustrating the configuration of channel segments 171 which are not visible in FIG. 7. This configuration allows contact with the gate all around the channel (170), hence the name. This allows even further increased control over both conductivity and magnetization, with even greater gains in process node scaling. FIG. 7 is a perspective view of the inventive GAAHET device 104. FIG. 10 is an elevation view of the front of the GAAHET device, from viewpoint A in FIG. 7. FIG. 11 is an elevation view of the back of the GAAHET device, from viewpoint C in FIG. 7. FIG. 13 is a side elevation view of the GAAHET device, from viewpoint B in FIG. 7. FIG. 14 is an overhead view of device 104.

A gate-less version of a GAAHET is possible so the device can be used in a CCVS mode similar to a FinHET.

### Fabrication

The MOSHET front-end-of-line (FEOL) assembly process is similar to that of the MOSFET, including the same basic steps:
Deposition
Photoresist coating
Lithography
Etch
Ion implantation
Packaging

The process of fabricating a MOSHET device may include the following steps:
Active Layer Deposition. The first deposition process utilizes a new wafer, which itself can either be silicon or a compound semiconductor (e.g., gallium arsenide/GaAs, gallium phosphide/GaP, etc.). A variety of methods can be used for actually depositing materials onto the wafer substrate, including molecular beam epitaxy, chemical vapor deposition and sputtering. Ion implantation may occur within this step to electrically dope the magnetic semiconductor.
Field Dielectric Deposition. After depositing the (anti-)ferromagnetic/ferrimagnetic semiconductor material as a thin film, a layer of polysilicon, high-k dielectric oxide (e.g., hafnium oxide/HfO₂, zirconium oxide/ZrO₂, etc.), or strontium titanate/SrTiO₃ is deposited via similar processes, using the magnetic semiconductor as a substrate to act as a field dielectric.
Photoresist Coat and Field Dielectric Etch. A layer of photoresist material is deposited, and regions of the material exposed by a photomask react to an applied ultraviolet light projected through a reticle. Resist material degraded by the ultraviolet exposure is then wet or dry etched away, leaving exposed areas as the active areas of the device, isolated by remaining dielectric material.
Doped Well Implantation. Exposed magnetic semiconductor material can then be further electrically doped with positive or negative ions to form p-type or n-type wells, respectively.
Gate Dielectric & Conducting Gate Material Deposition. High-k dielectric material or SrTiO₃ is deposited as a thin film, and the conducting gate material is also deposited thereafter. The conducting gate material can be polysilicon or, in the case of the antiferromagnetic embodiment of the device, for example bismuth ferrite/BiFeO₃.
Gate Material Etch. The field effect deposition step (above) is repeated using a photomask for the creation of the gate layer. All material except for that on gate regions is etched away.
Source and Drain Ion Implantation. The photoresist coat and field dielectric etch process (above) is repeated to implant source regions and drain regions in the substrate. If the substrate is p-doped, sources and drains are n-doped and vice versa. Conversely, if the substrate is p-doped with an n-well previously implanted, then the source and drain in the n-well are p-doped.
Aluminum Deposition and Oxidation. A thin aluminum layer is deposited and oxidized to form aluminum oxide as an insulating passivation layer. Similar materials can be used in this step, including aluminum nitride through separate processes.
Aluminum Oxide/Nitride Etch. The gate material etch process (above) is repeated, leaving only the gate, source and drain regions partially exposed with an aluminum oxide passivation layer over part of the source, part of the drain, part of the gate, and the field oxide layer.
Metal Deposition. A moderate-to-high conductivity metal/alloy (e.g., aluminum, copper, etc.) is deposited onto the device.
Metal Etch. The aluminum oxide/nitride etch process is repeated, leaving only part of the aluminum oxide above the gate material exposed. This metal serves as the electrical contacts for the gate of the device and between adjacent devices (connecting the drain of one device to the source of another).

For a full system or chip using the trancitor, this process can have multiple repetitions, depending on the gate length/node size, the configuration of the device (e.g., planar, FinHET, GAAHET, etc), and specific system requirements and constraints. As such, the whole process can be repeated dozens of times more on a single wafer to finish the chip; in particular, metal deposition and metal etch steps can be repeated more than ten times each to finish the back-end-of-line (BEOL) processing, allowing the chip to be ready for use

### ABBREVIATIONS

| | |
|---|---|
| MOS | metal oxide semiconductor |
| MOSFET | metal-oxide-semiconductor field-effect transistor |
| FinFET | fin field-effect transistor |
| GAAFET | gate-all-around field-effect transistor |
| CCVS | current-controlled/voltage source device |
| VCVS | voltage-controlled/voltage source device |
| VCCS | voltage controlled/current source device |
| CCCS | current controlled/current source device |
| MOSHET | metal-oxide-semiconductor Hall-effect trancitor |
| AHE | anomalous Hall effect |
| FinHET | fin Hall-effect trancitor |
| GAAHET | gate all-around Hall effect trancitor |
| FEOL | front-end-of-line |
| STI Dielectric | shallow trench isolation dielectric |
| TMR | tunneling magnetoresistance |

### DRAWINGS LEGEND

| | |
|---|---|
| 100 | Planar MOSHET Device (Trancitor) |
| 102 | FinHET variation (Trancitor) |
| 104 | GAAHET variation (Trancitor) |
| 110 | Source |
| 111 | Source segmented |
| 120 | Drain |
| 121 | Drain segmented |
| 122 | Fin in FinHET and GAAHET |
| 124 | Interstitial space in GAAHET devices |
| 130 | Gate |
| 140 | Dielectric layer, also termed insulating layer |
| 142 | Tap dielectric |
| 144 | Shallow trench isolation layer |
| 150 | Body terminal |
| 152 | Substrate layer |
| 154 | Floating gate |
| 160 | Tap/Hall contact |
| 162 | Tap/Hall contact, opposite polarity to 160 |
| 170 | Channel |
| 171 | Channel in GAAHET embodiment |
| 172 | Active layer |
| 174 | Secondary Insulating Layer/ Barrier |
| 180 | Source side |
| 182 | Drain side |

### REFERENCES

(1) WU CHENG-HSIEN; KO CHIH-HSIN; WANN CLEMENT HSINGJEN. Method of Forming CMOS FinFET Device. US2013/0168771 A1.
(2) LEE HEON BOK; KIM CHUL SUNG; HYUN SANG JIN. Semiconductor Devices Including Recessed Source/Drain Silicides and Methods of Forming the Same. US 2019/0074362 A1.
(3) Lee, S. A Missing Active Device-Trancitor for a New Paradigm of Electronics. IEEE Access 2018, 6, 46962-46967. https://doi.org/10.1109/ACCESS.2018.2866883.
(4) Pontes, F. M.; Lee, E. J. H.; Leite, E. R.; Longo, E.; Varela, J. A. High Dielectric Constant of SrTiO3 Thin Films Prepared by Chemical Process. J Mater Sci 2000, 35 (19), 4783-4787. https://doi.org/10.1023/A: 1004816611050.
(5) Tan, Q.; Wang, Q.; Liu, Y. Magnetic Properties and Spontaneous Polarization of La−, Mn-and N-Doped Tetragonal BiFeO3: A First-Principles Study. Materials 2018, 11 (6). https://doi.org/10.3390/ma11060985.
(6) Shao, D.-F.; Zhang, S.-H.; Gurung, G.; Yang, W.; Tsymbal, E. Y. Nonlinear Anomalous Hall Effect for Néel Vector Detection. Phys Rev Lett 2020, 124 (6), 067203. https://doi.org/10.1103/PhysRevLett. 124.067203.
(7) Ramesh, R. Materials for a Sustainable Microelectronics Future: Electric Field Control of Magnetism with Multiferroics. Journal of the Indian Institute of Science. Springer Jan. 1, 2022, pp 489-511. https://doi.org/10.1007/s41745-021-00277-7.
(8) Yan, H.; Feng, Z.; Qin, P.; Zhou, X.; Guo, H.; Wang, X.; Chen, H.; Zhang, X.; Wu, H.; Jiang, C.; Liu, Z. Electric-Field-Controlled Antiferromagnetic Spintronic Devices. Advanced Materials 2020, 32 (12), 1905603. https://doi.org/10.1002/adma.201905603.
(9) Šmejkal, L.; González-Hernández, R.; Jungwirth, T.; Sinova, J. Crystal Time-Reversal Symmetry Breaking and Spontaneous Hall Effect in Collinear Antiferromagnets. Sci. Adv 2020, 6. https://doi.org/10.1126/sciadv.aaz8809.
(10) Liu, C.; Wang, Y.; Sun, H.; Ma, C.; Luo, Z.; Wang, H.; Yin, Y.; Li, X. Positive-to-Negative Subthreshold Swing of a MOSFET Tuned by the Ferroelectric Switching Dynamics of BiFeO3. NPG Asia Mater 2021, 13 (1). https://doi.org/10.1038/s41427-021-00345-5.
(11) Ding, H.-C.; Duan, C.-G. Electric-Field Control of Magnetic Ordering in the Tetragonal-like BiFeO. EPL (Europhysics Letters) 2012, 97 (5), 57007. https://doi.org/10.1209/0295-5075/97/57007.
(12) Feng, Z.; Zhou, X.; Šmejkal, L.; Wu, L.; Zhu, Z.; Guo. H.; González-Hernández, R.; Wang, X.; Yan, H.; Qin, P.; Zhang, X.; Wu, H.; Chen, H.; Xia, Z.; Jiang, C.; Coey, M.; Sinova, J.; Jungwirth. T.; Liu, Z. Observation of the Anomalous Hall Effect in a Collinear Antiferromagnet; 2020. https://doi.org/https://doi.org/10.48550/arXiv.2002.08712.
(13) Grzybowski, M. J.; Wadley, P.; Edmonds. K. W.; Campion, R. P.; Dybko, K.; Majewicz, M.; Gallagher, B. L.; Sawicki, M.; Dietl, T. Gating Effects in Antiferromagnetic CuMnAs. AIP Adv 2019, 9 (11). https://doi.org/10.1063/1.5124354.
(14) Wadley, P.; Novák, V.; Campion, R. P.; Rinaldi, C.; Martí, X.; Reichlová, H.; Železný, J.; Gazquez, J.; Roldan, M. A.; Varela, M.; Khalyavin, D.; Langridge, S.; Kriegner, D.; MácA, F.; Mašek, J.; Bertacco, R.; Holý, V.; Rushforth, A. W.; Edmonds, K. W.; Gallagher, B. L.; Foxon, C. T.; Wunderlich, J.; Jungwirth, T. Tetragonal Phase of Epitaxial Room-Temperature Antiferromagnet CuMnAs. Nat Commun 2013, 4. https://doi.org/10.1038/ncomms3322.
(15) Deng, Z.; Jin. C. Q.; Liu, Q. Q.; Wang, X. C.; Zhu, J. L.; Feng, S. M.; Chen, L. C.; Yu, R. C.; Arguello, C.; Goko, T.; Ning. F.; Zhang, J.; Wang, Y.; Aczel, A. A.; Munsie, T.; Williams, T. J.; Luke, G. M.; Kakeshita, T.; Uchida, S.; Higemoto, W.; Ito, T. U.; Gu, B.; Maekawa, S.; Morris, G. D.; Uemura, Y. J. Li(Zn,Mn) As as a New Generation Ferromagnet Based on a I-II-V Semiconductor. Nat Commun 2011, 2 (1). https://doi.org/10.1038/ncomms1425.
(16) Feng, Z.; Zhou, X.; Šmejkal, L.; Wu, L.; Zhu, Z.; Guo. H.; González-Hernández, R.; Wang, X.; Yan, H.; Qin, P.; Zhang, X.; Wu, H.; Chen, H.; Xia, Z.; Jiang, C.; Coey, M.; Sinova, J.; Jungwirth. T.; Liu, Z. Observation of the Anomalous Hall Effect in a Collinear Antiferromagnet; 2021. https://doi.org/10.48550/arXiv.2002.08712.
(17) Yan, H.; Feng, Z.; Qin, P.; Zhou, X.; Guo, H.; Wang, X.; Chen, H.; Zhang, X.; Wu, H.; Jiang, C.; Liu, Z.; Yan, H.; Feng, Z.; Qin, P.; Zhou, X.; Guo, H.; Wang, X.; Chen, H.; Zhang, X.; Wu, H.; Jiang, C.; Liu, Z. Electric-Field-Controlled Antiferromagnetic Spintronic Devices. Advanced Materials 2020, 32, 1905603. https://doi.org/10.1002/adma.201905603.
(18) Nagaosa, N.; Sinova, J.; Onoda, S.; MacDonald, A. H.; Ong, N. P. Anomalous Hall Effect. Rev. Mod. Phys. 2009. 82 (2), 1539. https://doi.org/10.1103/RevModPhys.82.1539.
(19) Liu, W.; Zhang, H.; Shi. J. A.; Wang, Z.; Song, C.; Wang, X.; Lu, S.; Zhou, X.; Gu, L.; Louzguine-Luzgin, D. v.; Chen, M.; Yao, K.; Chen, N. A Room-Temperature Magnetic Semiconductor from a Ferromagnetic Metallic Glass. Nat Commun 2016, 7. https://doi.org/10.1038/ncomms13497.
(20) Tu, N. T.; Hai, P. N.; Anh, L. D.; Tanaka, M. (Ga,Fe) Sb: A p-Type Ferromagnetic Semiconductor. Appl Phys Lett 2014, 105 (13), 132402. https://doi.org/10.1063/1.4896539.
(21) Tu, N. T.; Hai, P. N.; Anh, L. D.; Tanaka, M. Heavily Fe-Doped Ferromagnetic Semiconductor (In,Fe)Sb with High Curie Temperature and Large Magnetic Anisotropy. Applied Physics Express 2019, 12 (10), 103004. https://doi.org/10.7567/1882-0786/ab3f4b.
(22) Wang, L.; Liu, T.; Wang, S.; Zhong, Z.; Jia, Q.; Jiang, Z. Fabrication and Ferromagnetism of Si-SiGe/MnGe Core-Shell Nanopillars. Nanotechnology 2016, 27 (40), 405705. https://doi.org/10.1088/0957-4484/27/40/405705.
(23) Huang, Y. L.; Nikonov, D.; Addiego, C.; Chopdekar, R. v.; Prasad, B.; Zhang, L.; Chatterjee, J.; Liu, H. J.; Farhan, A.; Chu, Y. H.; Yang, M.; Ramesh, M.; Qiu, Z. Q.; Huey, B. D.; Lin, C. C.; Gosavi, T.; Íñiguez, J.; Bokor, J.; Pan, X.; Young, I.; Martin, L. W.; Ramesh, R. Manipulating Magnetoelectric Energy Landscape in Multiferroics. Nat Commun 2020, 11 (1). https://doi.org/10.1038/s41467-020-16727-2.
(24) Labella, V. P.; et al. U.S. Pat. No. 7,405,086 B2 ABOVE ROOM TEMPERATURE FERROMAGNETCSILICON, 2008.
(25) Zhu, J. G. (Jimmy); Park, C. Magnetic Tunnel Junctions. Materials Today 2006, 9 (11), 36-45. https://doi.org/10.1016/S1369-7021(06)71693-5.
(26) Chen, A.; Wen, Y.; Fang, B.; Zhao, Y.; Zhang, Q.; Chang, Y.; Li, P.; Wu, H.; Huang, H.; Lu, Y.; Zeng, Z.; Cai, J.; Han, X.; Wu, T.; Zhang, X.-X.; Zhao, Y. Giant Nonvolatile Manipulation of Magnetoresistance in Magnetic Tunnel Junctions by Electric Fields via Magnetoelectric Coupling. Nat Commun 2019, 10 (1), 243. https://doi.org/10.1038/s41467-018-08061-5.

1. A metal-oxide-semiconductor voltage controlled anomalous Hall-effect trancitor (MOSHET) (100), comprising:
a. A semiconductor substrate (152), an active layer (172) and channel (170) wherein the active layer and channel each are formed from a ferromagnetic, ferrimagnetic, or antiferromagnetic material;
b. a source terminal (110) and drain terminal (120), and two Hall effect terminals (160/162) orthogonal to the source and drain terminals on the channel, a body terminal (150), and a gate terminal (130);
c. wherein a voltage applied to the gate terminal increases the conductivity of the channel (170) between the source and drain in an enhancement mode and reduces the conductivity of the channel in a depletion mode; and
d. wherein application of an electric field through the channel between the gate and body produces a Berry curvature in the channel that causes an anomalous Hall effect (AHE) that generates a voltage between the two Hall effect terminals.

2. The MOSHET of claim 1 wherein the channel (170) is a cube or cuboid having three orthogonal axes through opposing faces of the cube or cuboid, wherein the axes comprise connections to: (1) the gate and substrate, (2) the source and drain; and (3) the two tap Hall terminals.

3. A metal-oxide-semiconductor anomalous Hall-effect trancitor (MOSHET), comprising:
a. a semiconductor substrate (152), an active layer (172) and channel (170) wherein the active layer and channel each are formed from a ferromagnetic or ferrimagnetic material;
b. a source terminal (110) and drain terminal (120), and two Hall effect terminals (160/162) orthogonal to the source and drain terminals on the channel, and a body terminal (150);
c. wherein application of a current through the channel between the source and the drain generates a voltage between the two Hall effect terminals from an intrinsic anomalous Hall effect (AHE);
d. wherein magnitude of the current in the channel (170) between the source and drain controls the AHE.

4. A three-dimensional metal-oxide-semiconductor voltage controlled anomalous Hall-effect trancitor (MOSHET) (102, 104), comprising a substrate (152) with a fin and gate structure (122, 130) wrapping around a channel (170), wherein a source (110) and drain (120) are contiguous with the channel, and wherein the source, channel, and drain are oriented perpendicular to the gate structure (130); wherein a shallow trench layer (144) wraps around each of the source in drain and in contact with the substrate; and wherein a pair of tap Hall terminals (160,162) are perpendicular to the substrate and adjacent to the drain fin and optionally have a dielectric layer (142) interposed between each terminal and the drain fin.

5. The three-dimensional MOSHET of claim 4, further comprising contact points at the gate (130), the lower surface (150) of the substrate, the source (110), the drain (120), and at each tap Hall terminal (160,162).

6. The three-dimensional MOSHET of claim 4, wherein a voltage at the gate (130) modulates the conductivity of channel (170) between the source and drain and an anomalous Hall effect at the fin (122).

7. The three-dimensional MOSHET of claim 4, further comprising contact points at the lower surface (150) of the substrate, the source (110), the drain (120), and at each tap Hall terminal (160,162).

8. The MOSHET of claim 4 (104), wherein the source, channel, and drain is subdivided into two or more segments (111, 171, 121) parallel to the substrate with an interstitial space (124) between each segment; wherein the source, channel, and drain segments each form a contiguous unit; and wherein optionally dielectric layers (140) are interposed between channel segments (171).

9. A metal-oxide-semiconductor anomalous Hall-effect trancitor comprising:
a. an active layer (172) supported by a substrate layer (152), a source (110) and drain (120), wherein the source (110) may be either a p-doped or n-doped semiconductor and the drain (120) is the inverse, n-doped or p-doped, respectively; wherein an intermediate active layer channel (170) is interposed between the source and drain; wherein the active layer (172) material is a magnetic semiconductor which can be crystalline or amorphous (metallic glass-based);
b. wherein orthogonal to both the primary gate and the source/drain terminal pair are two tap Hall terminals (160, 162), which measure the output voltage from the anomalous Hall effect within the channel.

10. The metal-oxide-semiconductor anomalous Hall-effect trancitor of claim 9, wherein the magnetic semiconductor is crystalline and comprises a Si-based, Il-IV, III-V semiconductor; or wherein the magnetic semiconductor is amorphous and comprises a metallic glass-based semiconductor.

11. The trancitor of claim 9, wherein the active layer material is a ferromagnetic, ferrimagnetic, or antiferromagnetic material.

12. The trancitor of claim 9, wherein the active layer magnetic semiconductor is amorphous CO_{28.6}Fe_{12.4}Ta_{4.3}B_{8.7}O₄₆ (a-CFTBO).

13. The trancitor of claim 1, wherein a secondary insulating layer (174) is sandwiched between the active layer (172) and the substrate layer (174), wherein the secondary insulating layer (174) is made of similar material to the primary insulating layer of the gate.

14. The trancitor of claim 1, wherein a thin layer of ferromagnetic, ferrimagnetic or antiferromagnetic material forming a gate layer (154) is sandwiched between the channel (170) and the substrate layer (152); wherein a magnetic anisotropy of the gate layer (154) remains fixed; wherein an electric field at the gate layer (154) modifies the magnetic anisotropy of layer (172) causing a magnetization rotation so that the relative magnetization configuration of layer (172) is modulated; and wherein the magnetic anisotropy of layer (172) creates a low resistance state and a high resistance state.
